(19) United States
(12) Patent Application Publication
(10) Pub. No.: US 2005/0161659 A1
(43) Pub. Date: Jul. 28, 2005

(54) Nanowire and electronic device

(75) Inventor: Erik Petrus Antonius Maria Bakkers, Eindhoven (NL)

Correspondence Address: JORDAN AND HAMBURG LLP, 122 EAST 42ND STREET, SUITE 4000, NEW YORK, NY, 10168, US

(73) Assignee: Yanmar Agricultural Equiptment Co., Osaka-shi (JP)

(21) Appl. No.: 10/509,598

(22) PCT Filed: Mar. 27, 2003
(86) PCT No.: PCT/IB03/01226

(30) Foreign Application Priority Data
Mar. 28, 2002 (EP) 020764288

(51) Int. Cl. H01L 29/06

(52) U.S. Cl. 257/9

(57) ABSTRACT

The nanowire (10) comprises a first region (1), a second region (2), and a third region (3), wherein the diameter (c) of the second region (2) is greater than the diameters (a) of the first and the third region (1, 3), therewith interrupting at least partially the quantization of the nanowire (10) and giving the second region a smaller bandgap. The second region (2) has a length (b) in axial direction of less than 100 nm, preferably less than 20 nm. The nanowire (10) can be used in an (opto-)electronic device having electrodes as a quantum dot, a single-electron transistor, or the like.

The invention relates to a nanowire having a first and a second region in an axial arrangement, which regions adjoin one another.

The invention also relates to an electronic device provided with a first and a second electrode which are interconnected by means of at least one nanowire.

The invention also relates to methods of manufacturing nanowires.

The invention further relates to a dispersion of nanowires.

Nanowires are wires of an—often semiconducting—material with a diameter of less than 100 nm. They are regarded as building blocks for future electronic and optoelectronic elements. The nanowires have the advantage that dimensional restrictions caused by photolithographic patterning become less relevant. In addition, nanowires have properties different from those of units of the same material but having greater dimensions because of quantization effects, such as a non-ohmic resistance.

Such a nanowire and such a device are known from Gudiksen et al., Nature, 415 (2002), 617-620. The known nanowire comprises a first region which is p-type doped and adjoining thereto in axial direction of the nanowire a second region which is n-type doped. A p-n junction is present between the two regions. The nanowire has a diameter of 20 to 50 nm and comprises semiconducting materials in two versions, such as GaP and GaAs; or n-type and p-type doped Si, and ditto InP. The electronic device with the wire may be used as a light-emitting diode and as a rectifier.

It is a disadvantage of the known nanowire that the promises of the nanoelectronics are essentially not fulfilled. The known wire performs known functions on a miniature scale, but it does not utilize the possibilities of quantization offered by a nanowire limited in two dimensions.

It is accordingly a first object of the invention to provide a nanowire in which the possibilities of the quantization are realized.

It is a second object of the invention to provide an electronic device of the kind mentioned in the opening section which comprises the nanowire according to the invention.

It is a third object of the invention to provide a dispersion of the nanowires according to the invention.

The first object is realized in a nanowire with a first, a second, and a third region in an axial arrangement, wherein the second region adjoins the first and the third region and has a length of less than 100 nm in axial direction, and the second region has a greater diameter than the first and the third region.

The second object is achieved in that the nanowire according to the invention is present as a connector between the first and the second electrode.

The third object is achieved in a dispersion of the nanowires according to the invention in a dispersing agent.

The second region is incorporated in the nanowire according to the invention such that this region has a smaller bandgap. It is achieved thereby that it is energetically most favorable for a charge carrier—i.e. an electron or a hole—to be present in this region. The result is that the electron distribution in the wire can be controlled highly purposely by means of the electrodes of the device: under certain circumstances the charge carrier is stuck in the second region, and no conduction between the first and the second electrode will be possible. Under other circumstances the charge carrier is energetically stimulated, so that it can overcome the energy barrier of the second region. Conduction between the first and the second electrode is possible then.

Novel electronic and optoelectronic elements are realized in a comparatively simple manner thereby. Examples are the “single electron transistor” which can act as a digital transistor, the “quantum dot memory” in which data can be stored digitally on a nanoscale, and an optoelectronic recombination center.

In a first embodiment of the nanowire according to the invention, the first and the third region have an average diameter of at most 10 nm in radial direction, and the second region has a greater diameter in radial direction. The two-dimensional quantization is at least partly lifted in the second region. This implies that more energy levels are present in the electron bands of the crystal. The number of levels k is indeed directly proportional to the extension of the crystal according to k=Nπ/a, in which a is the mutual distance of the atoms and N the number of atoms in a certain (crystal) direction. In the second region, the number of atoms N in radial direction is greater than in the first and the third region. This means that there are more energy levels. The quantization, which means in essence a non-overlap of the various energy levels, is accordingly not present or to a lesser degree. That means that the bandgap—i.e. the distance between an occupied energy level and the next, non-occupied energy level—is smaller, and accordingly a charge carrier will have more of a chance of dropping down to a lower energy level.

It is favorable if the local, at least partial lifting of the two-dimensional quantization is limited to a small area. Preferably, therefore, the second region has a small length of 20 nm or less in axial direction. In radial direction, its diameter is preferably smaller than 50 nm, more preferably approximately equal to the length of the second region. It is furthermore favorable if the first and the third region have a very small diameter of less than 10 nm, more preferably less than 5 nm. The length in axial direction of the first and the third region is preferably more than 10 nm, more preferably more than 50 nm and less than 2000 nm. A nanowire having such a length and a very small diameter can be manufactured and is stable. A nanowire having such a length can moreover be readily adhered to an electrode structure.

It is not necessary in the nanowire according to the invention that the first and the third region have substantially the same diameter. The only condition is that quantization effects are present in the first and the third region. It may indeed be an advantage to construct the nanowire asymmetrically, for example for realizing a rectifier function. The diameter of the first region then is, for example, 5 nm, whereas the diameter of the third region is, for example, 10 nm.

In a further embodiment of the nanowire according to the invention, furthermore, a fourth and a fifth region are present, in which fourth region the quantization is at least partly lifted by means of a greater diameter and/or some other structural difference, while the fifth region does show quantization effects. It is accordingly possible in the nanowire according to the invention to define a structure which involves more than just a single interruption of the quantization. Such a structure is favorable, for example, as a “multiple quantum dot”, in which a discrete number of states can be stored. It is possible in this manner to build a new type of digital memory.

In a further embodiment of the nanowire according to the invention, the nanowire comprises a different material in the second region of greater diameter, which material has a smaller bandgap than that of the first and the third region. An example of this that the first and the third region comprise Si and the second region SiGe. Alternatively, the second region may comprise SiC. It is also possible for the SiGe also to comprise C. The use of a material with a smaller bandgap in the second region enhances the effect of the partial lifting of the quantization.

In an alternative embodiment of the nanowire according to the invention, the nanowire has a different doping in the second region with respect to the first and the third region. An example of this is a p-type doping in the second region and an n-type doping in the first and the third region. This creates a p-n-p junction or transistor, in which the quantization is partly lifted in the n-region. This renders it possible to optimize the properties of the n-region for inlet and/or output coupling of light. If the second region has a somewhat greater length, for example of the order of 80 nm, it is in addition quite possible to define contacts at the second region. This is possible, for example, by means of photolithographic techniques. The same holds by analogy for an n-p, in particular an n-p-n junction or transistor. Such a junction may very well be used as a light-emitting diode (LED). The recombination of charge carriers in fact takes place preferably in the p-type region in an LED; a smaller bandgap for this region results in a higher efficacy.

It is a further advantage of such a nanowire, in which the second region of greater diameter in addition comprises a different material or a different doping, that it can be readily manufactured by etching techniques. The etchants used have a different etching rate for the other material or the other doping, resulting in a variation of the obtained diameter. This is true in particular for anodic etching and for thermal oxidation and final etching of the nanowires at an elevated temperature.

It is furthermore preferred that the transition between the first and the second, and between the second and the third region is abrupt. The result of such an abrupt transition is that the second region will have a cylindrical shape. The formation of such an abrupt transition is possible when the manufacturing process is well controlled. It may also be desirable to give the second region an oval or round shape in that a gradual transition from the first to the second region and from the third to the second region is realized.

The nanowire according to the invention preferably comprises one or several semiconducting materials. Among the examples are Si, SiC, SiGe, GaAs, InP, InAsP. It is alternatively possible that the first and the third region comprise a metallic material, and the second region comprises a semiconducting material.

The nanowires can be used not only for specific functions in a larger circuit, but an entire circuit based on nanowires can be realized. Preferably, the electrodes therein form the contacts to which the various nanowires are connected. Alternatively, the nanowires may be used for discrete transistors, for example in thin-film transistors which provide the control of picture screen pixels.

In a favorable embodiment of the device according to the invention, the nanowire having a first, a second, a third, a fourth, and a fifth region is present, wherein the quantization is at least partly interrupted in the second region and in the fourth region. A first and a second gate electrode are also present. The first and the second gate electrode are separated from the nanowire by a dielectric layer and are interconnected in an electrically non-conductive manner. A perpendicular projection of the first gate electrode on the nanowire has an overlap with the second region, and a perpendicular projection of the second gate electrode on the nanowire has an overlap with the fourth region. A transistor having several gate electrodes is obtained in this manner. Each of the gate electrodes then controls a region of the nanowire which has a smaller bandgap and in which the quantization is partly lifted. To keep the capacitive coupling between the first and the second gate electrode limited, it is favorable if the third region has a length of more than 300 nm, more preferably more than 1000 nm. Nanowires may also be used for the gate electrodes.

It is a fourth object of the invention to provide methods by which nanowires according to the invention can be manufactured.

This object is achieved in a method of manufacturing nanowires by means of catalytic growth, wherein the second region is grown at a higher temperature than the first and the third region.

The object is also achieved in a method of manufacturing nanowires according to the invention, comprising the steps of:
providing a patterned etching mask on a surface of a semiconductor substrate; and
etching the semiconductor substrate so as to form nanowires in a direction substantially perpendicular to the surface, during which the semiconductor substrate is etched in a first, a second, and a third layer, which correspond to the first, the second, and the third region of the nanowires, under different conditions.

It was found that nanowires according to the invention can be manufactured in that the conditions during growing or during etching are adapted such that more material is deposited in the second region or less material is etched away. The kinetics of these processes can be set in a manner known per se, in particular through adjustment of the concentrations of certain substances or intermediate products, adjustment of the temperature, and adjustment of the potential in an electrochemical process. It is particularly favorable to use the temperature for adjustment of the conditions in the case of growing in a “vapor-liquid-solid” process, which is known to those skilled in the art. The etching method used may be reactive ion etching, dry etching, and anodic etching. A method of manufacturing nanowires by anodic etching is described in the application EP 02075950.2 (NL020199) not previously published, which is incorporated herein by reference.

If not only a geometric variation in the diameter, but also a material variation of the nanowire is desired, it is preferred to manufacture the latter in that a semiconductor substrate is etched by means of reactive ion etching or dry etching. It is necessary then to choose a semiconductor substrate in which layers of the desired composition and/or doping are provided or which is substantially built up from such layers. Such layers may be provided in a semiconductor substrate, for example, by means of epitaxial growth.

In a preferred embodiment, the nanowires are removed from the substrate after the growth. This allows to use them in a dispersion, for application onto a substrate. However, for other applications such as display elements and optical storage elements it may be advantageous to provide an array of nanowires on the substrate. The nanowires can be removed with ultrasonic vibrations, for instance.

These and other aspects of the nanowire and the electronic device according to the invention will be explained in more detail with reference to drawings and non-limitative embodiments, with:

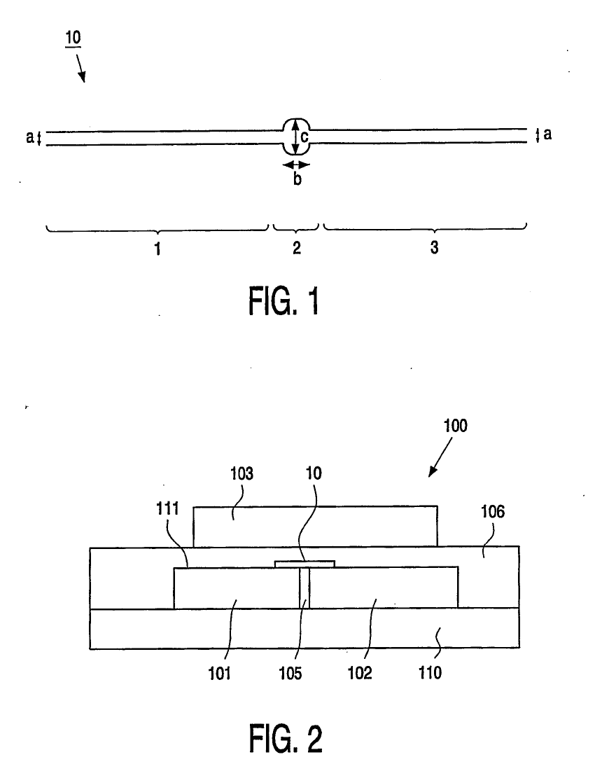

FIG. 1 showing a nanowire, and

FIG. 2 showing an electronic device with a nanowire.

FIG. 1 shows a nanowire 10 according to the invention with a first region 1, a second region 2, and a third region 3. The diameter c of the second region 2 is greater than the diameters a of the first and the third region 1, 3. This interrupts at least partly the quantization of the nanowire 10 and gives the second region 2 a smaller bandgap. The second region 2 has a length b in axial direction of preferably less than 100 nm, more preferably less than 20 nm. The nanowire 10 may be used in an electronic device 100 as shown in FIG. 2, where the nanowire 10 is present between a first and a second electrode 101, 102. The entire assembly may then form inter alia a single-electron transistor, a quantum dot memory, or an optoelectronic element.

### Embodiment 1

A thin gold layer of 0.5 to 3 nm is present on a silicon semiconductor substrate with an oxidized surface. This semiconductor substrate is placed in a quartz tube at a first end of a furnace. A fixed target of InP is placed at a second end of the furnace such that ablated InP can be carried along by the gas flow to the substrate. The furnace is evacuated to below 10 Pa. Then the pressure is set for 3.10⁴ Pa with an Ar flow of 100 to 300 sccm. The furnace is heated to 500° C. This breaks open the gold layer and forms clusters on a nanometer scale. At this temperature, the target is ablated with an ArF laser having a wavelength of 193 nm. This leads to a growth of nanowires 10 of InP with the Au clusters acting as catalysists. The nanowires obtained comprise a first region 1, a second region 2, and a third region 3.

After the first region 1 of the nanowire 10 having a length of 200 nm—in general 100 to 1000 nm—and a diameter of 10 nm has been grown, the temperature is raised to 550 to 600° C. The result of this is that more InP is dissolved in the Au clusters, whereby the volume of the clusters increases. It also has the result that the wire being grown becomes thicker. The second region 2 is thus formed with a diameter of 15 to 50 nm. The diameter of the first region, however, does not increase because a higher laser pulse frequency is used. After a period of 10 to 60 seconds, the temperature is lowered to 500° C. again. At this temperature, a third region 3 of the nanowire 10 is grown until a nanowire 10 with a total length of approximately 200 to 2000 nm has been created. The result is a nanowire having a shape as shown in FIG. 1, with the diameter of the first and the third region (a) equal to 10 nm, the length in axial direction of the second region (b) equal to 15 nm, and the diameter of the second region (c) between 15 and 50 nm. The length of the first and the third region, which is 100 nm in this example, may be chosen to be greater if so desired, up to the micrometer order of magnitude.

### Embodiment 2

Au clusters are formed on a substrate in the same manner as in embodiment 1. Then silicon nanowires are grown by chemical vapor deposition at 450° C. in an atmosphere of 3 cm³ STP per minute of silane and 100 ppm phosphene in 18 cm³ STP per minute of He. After a wire of 100 to 1000 nm has thus been grown, the temperature is raised to 500° C. The result of this is that more Si is dissolved in the Au clusters, whereby the volume and thus the diameter of the clusters increases. The result is a local widening of the wire to 15-50 nm, thus forming the second region. After 10 to 60 seconds, the temperature is reduced to 450° C. again. The wire is grown further at this temperature until a nanowire with a total length of 200 to 2000 nm has been created.

### Embodiment 3

A photosensitive double layer consisting of a 400 nm thick lower layer of hardbaked Shipley AXS 1813 and an 80 nm thick top layer of e-beam resist comprising negative silicones is provided on a semiconductor substrate. This is patterned by means of radiation (e-beam, 100 kV, 100 μC/cm²), such that isolated regions are defined. These isolated regions have a diameter of 50×50 nm and are distanced from one another by 1.0 μm. The top layer is developed, and subsequently dipped in isopropyl alcohol. Then the pattern is anisotropically transferred from the top layer to the lower layer in a 0.3 Pa oxygen plasma etching step at a low rf power density of 0.07 W/cm² and a dc bias of −170 V.

The semiconductor substrate is then etched in a direction substantially perpendicular to the surface. This is done by dry etching with an inductively coupled plasma (ICP) setup in which an etching step and a passivating step are performed in alternation. The treatment is rf-controlled (13.56 MHz). A gas mixture of SF₆/O₂/C₄F₈ is used for the etching step. Standard values here are an SF₆ gas flow of 130 sccm, an O₂ gas flow of 13 sccm, and a C₄F₈ gas flow of 40 sccm at a pressure of approximately 2 Pa. The gas used for the passivating step is C₄F₈ with a gas flow of 140 sccm. The standard duration of an etching step and a passivating step is 8 seconds.

Etching takes place largely in three stages. In the first stage, a pore is etched with a tapering diameter. This is achieved in that the etching step is performed in a shorter time or less intensively than the passivating step. The result is that the passivating layer provided during the passivating step is entirely removed only in the pit of the pore. A portion of the passivating layer remains at the walls of the pore, where accordingly a passivating layer is deposited on a passivating layer. This has the result that the pore becomes increasingly narrower.

In the second stage, the etching step is more intensive and/or lasts longer than the passivating step. This has the result that the pit of the pore is widened to approximately the original diameter.

In the third stage, the etching steps and the passivating steps are very short. This has the result that the narrowing of the pore, or the projection of the wall, is not or substantially not etched away. The large number of short etching and passivating steps has the result that the projection is embedded in the passivating layer. In the pit of the pore, however, the passivating layer is completely removed each time, the result being isotropic etching.

The semiconductor substrate is etched down to a depth of approximately 0.5 μm and leads to nanowires. Said projection of the wall forms the second region of greater diameter. The substrate is subsequently heated in an oxygen atmosphere to approximately 850° C. during 2 hours. The silicon is thermally oxidized thereby. Then the semiconductor substrate is placed in a bath with hydrogen fluoride in a concentration of approximately 5 mole per liter. A circulation is maintained in the bath to keep the composition of the bath constant. The result is that the nanowires are given a diameter of 10 nm in the first and the third region. In the second region, where the initial thickness was greater, the thickness is still greater after this treatment. The semiconductor substrate with the nanowires is placed in an ethanol bath. This bath is placed in an ultrasonic device. The nanowires are detached from the substrate by ultrasonic vibration.

The dispersion of the wires thus formed is provided on a silicon substrate. Electrical contacts were photolithographically defined in a dual layer of 2 nm Ti and 10 nm Au by means of electron radiation (e-beam). Heating took place up to 400° C. after the application of the wires.

### Embodiment 4

A layer of Si with a p-type doping is epitaxially grown on a semiconductor substrate with an n-type doping (doping level 10¹⁹ atoms/cm³). The thickness of the grown layer is approximately 10 to 30 nm. A Si layer is epitaxially grown thereon with an n-type doping. The thickness of the grown layer is approximately 300 nm, in general between 100 and 1000 nm. The resulting substrate is subjected to the patterning and etching treatments as described in embodiment 3. Nanowires with internal n-p-n junctions, with the p-region having a greater diameter, were obtained in this manner.

### Embodiment 5

An etching mask is provided at a surface of a semiconductor substrate. The etching mask has openings of 1.5 μm diameter at regular mutual distances. Pointed indentations are defined through the etching mask by means of a KOH etching treatment. Then the semiconductor substrate is placed in an anodic cell. The rear surface of the semiconductor substrate is then in a potassium sulphate solution such that this rear side is connected with electrical conduction to an anode. The surface of the semiconductor substrate is in a hydrogen fluoride solution. The substrate is anodically etched in that the current density is set for a value of between 0.9 and 1 time the peak current density as specified in more detail in the application EP 02075950.2 (NL020199) not previously published, which is incorporated herein by reference. Nanowires are formed thereby. A local widening of the nanowires is achieved in that a lower current density is used temporarily.

### Embodiment 6

FIG. 2 is a diagrammatic cross-sectional view of a semiconductor element 100, being a thin-film transistor. A source electrode 101 and a drain electrode 102 are provided on a substrate 110 of polyimide. The electrodes 101, 102 comprise, for example, Au and are lithographically defined. The electrodes 101, 102 are mutually separated by a channel 105 which comprises a dielectric material with preferably a low dielectric constant. Suitable materials are known to those skilled in the art, among them silicon dioxide, hydrogen silsesquioxane and methyl silsesquioxane, porous silica, SiLK, and benzocyclobutene. The choice of material also depends on the choice of substrate. The surface 111 of the electrodes 101, 102 and the channel 105 is planarized, so that nanowires 10 are present on a substantially planar surface 111. The nanowires 10 are laid down and aligned in that a droplet of a dispersion with the nanowires is provided on the surface 111, while a voltage is being applied. The applied electric field of 0.1 to 1 V/μm at a frequency of 0.1 to 10 kHz causes an alignment of the nanowires 10. A dielectric layer 106 lies on the nanowires 10, separating the gate electrode 103 from the nanowires 10. Alternatively, alignment may be achieved in that a mold with channels is provided on the surface 11 and the entire assembly is placed in a bath containing the dispersion of nanowires. A flow is then induced by means of a pressure difference, whereby the nanowires are sucked into the channels of the mold. This leads to an arrangement of aligned nanowires 10.

As will be clear to those skilled in the art, an electronic device preferably comprises a large quantity of semiconductor elements 100 which are interconnected in a desired pattern and form a circuit. It is further noted that one or a large number of nanowires 10 may be present in a single semiconductor element 100, and that various materials may be chosen for the substrate 110, the electrodes 101, 102, 103, and the dielectric layers 105, 106, as is familiar to those skilled in the art of thin-film transistors.

1. A nanowire with a first, a second, and a third region in an axial arrangement,
wherein the second region adjoins the first and the third regions and has a length of less than 100 nm in axial direction, and
wherein the second region has a greater diameter than the first and the third region, in which first and third regions quantization effects take place.

2. A nanowire as claimed in claim 1, characterized in that the second region has a length in axial direction of less than 20 nm.

3. A nanowire as claimed in claim 1, characterized in that the first and the third region have an average diameter in radial direction of at most 10 nm.

4. A nanowire as claimed in claim 3, characterized in that the second region has a maximum diameter of 50 nm.

5. A nanowire as claimed in claim 1, characterized in that the first region is n-type doped and the second region is p-type doped.

6. A nanowire as claimed in claim 1, characterized in that a fourth and a fifth region are present, which fourth region is enclosed in axial direction by the third and the fifth region and in axial direction has a length of less than 100 nm, and which fourth region is structurally different from the third and fifth regions in that it has a smaller bandgap.

7. An electronic device provided with a first and a second electrode which are interconnected by means of at least one nanowire, characterized in that the nanowire as claimed in claim 1 is present.

8. An electronic device as claimed in claim 7, characterized in that the nanowire of claim 6 is present, and in that a first and a second gate electrode are present, wherein a perpendicular protection of the first gate electrode on the nanowire overlaps the second region and a perpendicular projection of the second gate electrode on the nanowire overlaps the fourth region.

9. A method of manufacturing nanowires as claimed in claim 1, by means of catalytic growth, wherein the second region is grown at a higher temperature than the first and the third region.

10. A method as claimed in claim 9, characterized in that the method comprises the steps of:
growing the first regions of the nanowires at a first growing temperature;
growing the second regions of the nanowires at a second growing temperature which is higher than the first growing temperature; and
growing the third regions of the nanowires at a third growing temperature which is lower than the second growing temperature.

11. A method of manufacturing nanowires as claimed in claim 1, comprising the steps of:
providing a patterned etching mask at a surface of a semiconductor substrate; and
etching the semiconductor substrate so as to form the nanowires in a direction substantially perpendicular to the surface, during which the etching rate is reduced while the second region of greater diameter is being formed.

12. A method as claimed in claim 11, wherein the nanowires are removed from the semiconductor substrate.

13. A dispersion of nanowires as claimed in claim 1, in a dispersing agent.
